(19) United States
(12) Patent Application Publication
(10) Pub. No.: US 2016/0233358 A1
(43) Pub. Date: Aug. 11, 2016

(54) POLYCRYSTALLINE FILMS COMPRISING COPPER-ZINC-TIN-CHALCOGENIDE AND METHODS OF MAKING THE SAME

(71) Applicant: WAKE FOREST UNIVERSITY, Winston-Salem, NC (US)

(72) Inventors: David CARROLL, Winston-Salem, NC (US); Yuan LI, Winston-Salem, NC (US); Wenxiao HUANG, Winston-Salem, NC (US)

(21) Appl. No.: 15/022,526

(22) PCT Filed: Sep. 16, 2014
(86) PCT No.: PCT/US2014/055883

§ 371 Date: Mar. 16, 2016

Related U.S. Application Data
(60) Provisional application No. 61/878,374, filed on Sep. 16, 2013.

(51) Int. Cl. H01L 31/032; H01L 21/477; H01L 29/66; H01L 31/0368; H01L 21/02; H01L 31/18

(52) U.S. Cl. CPC H01L 31/0326; H01L 21/02568; H01L 21/02595; H01L 21/02601; H01L 21/02628; H01L 31/1864; H01L 29/66969; H01L 31/0368; H01L 21/477

(57) ABSTRACT

In one aspect, methods of making a polycrystalline film are described herein. In some embodiments, a method of making a polycrystalline film comprises providing a nanoparticle composition comprising crystalline nanoparticles of copper-zinc-tin-chalcogenide disposed in a liquid carrier, wherein inorganic ligands are associated with surfaces of the copper-zinc-tin-chalcogenide nanoparticles, the inorganic ligands formed of a metal chalcogenide complex. The method further comprises depositing the nanoparticle composition on a substrate surface and removing the liquid carrier to provide the polycrystalline film of copper-zinc-tin-chalcogenide.

### CROSS REFERENCE TO RELATED APPLICATION

This application claims priority to U.S. Patent Application No. 61/878,374, filed on Sep. 16, 2013, the entirety of which is hereby incorporated by reference.

### FIELD

This invention relates to copper-zinc-tin-chalcogenides and, in particular, to nanoparticle compositions and films comprising a copper-zinc-tin-chalcogenide.

### BACKGROUND

Thin films formed from the kesterite material copper-zinc-tin-sulfide (CZTS) have received increasing attention in recent years due to the low cost, low toxicity and high abundance of CZTS and its constituent components. In addition, CZTS thin films can exhibit a high optical absorption coefficient and an optical bandgap suitable for use in solar energy applications. However, existing methods of forming CZTS thin films suffer from various disadvantages. For example, some methods require high-temperature (>500° C.) annealing under corrosive and/or toxic atmosphere to provide thin films of desired optoelectronic properties. Other methods require many iterative process steps to provide films of desired thickness. Moreover, some existing methods require the use of harsh processing conditions, resulting in film cracking and/or void formation due to high weight losses through desorption of tin sulfide, sulfur diffusion into molybdenum back contacts, and/or the formation of undesired secondary phases at a CZTS/contact interface.

### SUMMARY

In one aspect, nanoparticle compositions are described herein which can be used to form thin films of copper-zinc-tin-chalcogenide in an inexpensive and efficient manner In addition, a nanoparticle composition described herein can permit a desired stoichiometry of copper-zinc-tin-chalcogenide to be maintained during film formation and annealing, including without the use of additional materials or processing steps.

A nanoparticle composition described herein comprises crystalline nanoparticles of copper-zinc-tin-chalcogenide disposed in a polar liquid carrier, wherein inorganic ligands are associated with surfaces of the copper-zinc-tin-chalcogenide nanoparticles. In some instances, the inorganic ligands are formed of a metal chalcogenide complex including one or more metallic elements selected from Groups IB, IIB, IIIA and IVA of the Periodic Table and one or more of sulfur, selenium and tellurium. Groups of the Periodic Table are listed herein according to the CAS designation. In other embodiments, inorganic ligands can be formed of a chalcogenide or chalcogenide complex. Moreover, the nanoparticles of copper-zinc-tin-chalcogenide and associated surface inorganic ligands can be dispersed throughout the polar liquid carrier.

In another aspect, methods of making films of copper-zinc-tin-chalcogenide are described herein which, in some cases, provide one or more advantages over prior methods. For example, a method described herein can be used to form a polycrystalline film of copper-zinc-tin-chalcogenide having desirable electronic properties, such as high carrier mobility, without the need for harsh processing conditions. A polycrystalline film of copper-zinc-tin-chalcogenide formed by a method described herein can have a carrier mobility of at least about 8 cm²/Vs or at least about 10 cm²/Vs.

A method of making a polycrystalline film, in some embodiments, comprises providing a nanoparticle composition comprising crystalline nanoparticles of copper-zinc-tin-chalcogenide disposed in a polar liquid carrier, wherein inorganic ligands are associated with surfaces of the copper-zinc-tin-chalcogenide nanoparticles, and depositing the nanoparticle composition on a substrate surface. The polar liquid carrier is removed to provide the polycrystalline film of copper-zinc-tin-chalcogenide. Inorganic ligands associated with the crystalline nanoparticles of copper-zinc-tin-chalcogenide can be formed of a metal chalcogenide complex, chalcogenide complex or chalcogenide.

The deposited polycrystalline film of copper-zinc-tin-chalcogenide can be heated or annealed. For example, the deposited polycrystalline film can be heated at a temperature in excess of 200° C. or in excess of 300° C. Alternatively, the deposited polycrystalline film of copper-zinc-tin-chalcogenide can be heated at a temperature no greater than about 250° C. Among other technical effects, heating the deposited polycrystalline film of copper-zinc-tin-chalcogenide can incorporate chalcogenide from the inorganic ligands into the polycrystalline film. Further, metal from the inorganic ligands can also be incorporated into the polycrystalline film of copper-zinc-tin-chalcogenide during heating. As discussed further herein, incorporation of inorganic ligand components into the polycrystalline film of copper-zinc-tin-chalcogenide can mitigate metal and/or chalcogenide loss in the film during heating operations. Such mitigation can preclude the use of toxic/corrosive atmospheres, such as H₂S or H₂Se, during crystalline film annealing.

Additionally, a method of making a polycrystalline film described herein, in some embodiments, can be carried out using a ligand-exchange procedure. For example, a method of making a polycrystalline film can comprise providing crystalline nanoparticles of copper-zinc-tin-chalcogenide having first ligands associated with surfaces of the nanoparticles; combining the nanoparticles with second ligands; replacing the first ligands with the second ligands on nanoparticle surfaces to provide ligand-exchanged nanoparticles; and dispersing the ligand-exchanged nanoparticles in a liquid carrier to provide a nanoparticle composition. The nanoparticle composition is deposited on a substrate surface and the liquid carrier is removed to provide the polycrystalline film of copper-zinc-tin-chalcogenide. Second ligands displacing the first ligands on surfaces of the crystalline nanoparticles of copper-zinc-tin-chalcogenide can demonstrate smaller spatial dimensions than the first ligands. For example, the second ligands can have shorter hydrocarbon chain lengths than the first ligands.

In still another aspect, electronic devices are described herein. In some embodiments, an electronic device comprises a first electrode or terminal, a second electrode or terminal, and a polycrystalline film in electrical communication with the first electrode or terminal and the second electrode or terminal, wherein the polycrystalline film comprises a copper-zinc-tin-chalcogenide film formed by a method described herein. The electronic device can comprise a photovoltaic device such as a solar cell or a field effect transistor. For example, in some cases, a photovoltaic device comprises a first electrode, a second electrode and a polycrystalline film described herein disposed between the first electrode and the second electrode. Further, a field effect transistor comprises a source terminal, a drain terminal, a gate terminal and a copper-zinc-tin-chalcogenide polycrystalline film described herein in electrical communication with the source terminal and the drain terminal. Other device architectures are also possible.

These and other embodiments are described in greater detail in the detailed description which follows.

### BRIEF DESCRIPTION OF THE DRAWINGS

FIG. 1 illustrates a sectional view of a photovoltaic device according to one embodiment described herein.

FIG. 2 illustrates a sectional view of an electronic device according to one embodiment described herein.

FIG. 3 illustrates a transmission electron microscopy (TEM) image of nanoparticles of a nanoparticle composition according to one embodiment described herein.

FIG. 4 illustrates scanning electron microscopy (SEM) images of polycrystalline films according to some embodiments described herein.

FIG. 5 illustrates the absorption profiles of polycrystalline films according to some embodiments described herein.

FIG. 6 illustrates the carrier mobilities of polycrystalline films according to some embodiments described herein.

### DETAILED DESCRIPTION

Embodiments described herein can be understood more readily by reference to the following detailed description, examples and drawings and their previous and following descriptions. Elements, apparatus and methods described herein, however, are not limited to the specific embodiments presented in the detailed description, examples and drawings. It should be recognized that these embodiments are merely illustrative of the principles of the present invention. Numerous modifications and adaptations will be readily apparent to those of skill in the art without departing from the spirit and scope of the invention.

In addition, all ranges disclosed herein are to be understood to encompass any and all subranges subsumed therein. For example, a stated range of “1.0 to 10.0” should be considered to include any and all subranges beginning with a minimum value of 1.0 or more and ending with a maximum value of 10.0 or less, e.g., 1.0 to 5.3, or 4.7 to 10.0, or 3.6 to 7.9.

All ranges disclosed herein are also to be considered to include the end points of the range, unless expressly stated otherwise. For example, a range of “between 5 and 10” should generally be considered to include the end points 5 and 10.

Further, when the phrase “up to” is used in connection with an amount or quantity, it is to be understood that the amount is at least a detectable amount or quantity. For example, a material present in an amount “up to” a specified amount can be present from a detectable amount and up to and including the specified amount.

### I. Nanoparticle Compositions

In one aspect, nanoparticle compositions are described herein. In some embodiments, a nanoparticle composition comprises crystalline nanoparticles of copper-zinc-tin-chalcogenide disposed in a polar liquid carrier, wherein inorganic ligands are associated with surfaces of the copper-zinc-tin-chalcogenide nanoparticles. In some cases, the inorganic ligands are formed of a metal chalcogenide complex. Alternatively, the inorganic ligands are formed of a chalcogenide or chalcogenide complex. Further, in some instances, surfaces of nanoparticle described herein are free or substantially free of hydrazine. Additionally, nanoparticles of copper-zinc-tin-chalcogenide having inorganic surface ligands can be dispersed throughout the polar liquid carrier of the composition.

Turning now to specific components, nanoparticle compositions described herein comprise crystalline nanoparticles of copper-zinc-tin-chalcogenide. The copper-zinc-tin-chalcogenide can have any chemical composition not inconsistent with the objectives of the present invention. A “chalcogenide,” for reference purposes herein, comprises an element of Group VIA of the Periodic Table, including oxygen (O), sulfur (S), selenium (Se), tellurium (Te), and polonium (Po). However, in some embodiments, a copper-zinc-tin-chalcogenide described herein does not comprise oxygen, tellurium, or polonium but instead comprises sulfur, selenium, or a combination thereof. For example, in some cases, nanoparticles of copper-zinc-tin-chalcogenide are of the formula CuₐZn_{b}Sn_{c}(S_{l-d}Se_{d})ₑ, wherein 1.2≦a≦2.5, 0.8≦b≦1.2, 0.5≦c≦1.5, 0≦d≦1 and 3.5≦e≦4.5. In some embodiments, a is about 2, b is about 1, c is about 1, and e is about 4. Alternatively, a<2 and c>1, such that the nanoparticles of copper-zinc-tin-chalcogenide are copper-poor and tin-rich. Moreover, in some embodiments, d=0, such that the copper-zinc-tin-chalcogenide comprises a copper-zinc-tin-sulfide. In other cases, d=1, such that the copper-zinc-tin-chalcogenide comprises a copper-zinc-tin-selenide. Moreover, in some instances, 0<d<1, such that the copper-zinc-tin-chalcogenide comprises a copper-zinc-tin-sulfide-selenide.

Nanoparticles of copper-zinc-tin-chalcogenide described herein can have any size and shape not inconsistent with the objectives of the present invention. For example, copper-zinc-tin-chalcogenide nanoparticles can have either an oblate shape or substantially spherical shape. Further, copper-zinc-tin-chalcogenide nanoparticles described herein have an average size in one, two or three dimensions of less than about 100 nm, less than about 50 nm, less than about 30 nm, less than about 20 nm, or less than about 10 nm. In some embodiments, copper-zinc-tin-chalcogenide nanoparticles have an average size in one, two or three dimensions of about 1 nm to about 100 nm or about 5 nm to about 50 nm.

Nanoparticle compositions also comprise inorganic ligands associated with surfaces of the copper-zinc-tin-chalcogenide nanoparticles. In some embodiments, the inorganic ligands are formed of a metal chalcogenide complex. A “metal chalcogenide” complex, for reference purposes herein, is a complex comprising a metal and a chalcogenide. In other instances, the inorganic ligands are formed of a chalcogenide or chalcogenide complex. A “chalcogenide complex,” for reference purposes herein, is a complex comprising a chalcogenide and at least one additional species. The additional species can be a second chalcogenide that differs from the first chalcogenide, or the additional species can be a non-metal or metalloid species. In some cases, the inorganic ligands comprise a mixture of species described herein, such as a combination of one or more metal chalcogenide complex ligands with one or more chalcogenide and/or chalcogenide complex ligands.

Any chalcogenide, chalcogenide complex or metal chalcogenide complex not inconsistent with the objectives of the present invention may be used as inorganic ligands. In some embodiments, a chalcogenide, chalcogenide complex or metal chalcogenide complex described herein does not comprise oxygen but instead comprises one or more of sulfur, selenium, and tellurium. Moreover, a chalcogenide, chalcogenide complex, or metal chalcogenide complex can be neutral or charged. For example, a chalcogenide complex or metal chalcogenide complex can be anionic. In addition, counter ions such as cations can be associated with charged inorganic ligands.

Suitable inorganic ligands described herein can have the formula [A]ₓ[B]_{y}, wherein 0≦x≦6 and 1≦y≦6. Further, A can be a metal cation such as an alkali metal cation, an alkaline earth cation, or a transition metal cation. A can also be NH₄⁺. In addition, B can be a metal chalcogenide, metal chalcogenide anion, metalloid chalcogenide, metalloid chalcogenide anion, hydrogen chalcogenide anion, or binary chalcogenide anion. Thus, in some cases, an inorganic ligand is an anion comprising at least one metal and at least one of S, Se, and Te. In some embodiments, an inorganic ligand is a metal chalcogenide complex formed of one or more metallic elements selected from Groups IB, IIB, IIIA and IVA of the Periodic Table and one or more of sulfur, selenium and tellurium. In some embodiments, the Group IIB element is mercury (Hg). In some embodiments, the Group IIIA element is indium (In). In some embodiments, the Group IVA element is tin (Sn). An inorganic ligand can comprise Sn₂S₆⁴⁻, Sn₂Se₆⁴⁻, In₂Se₄²⁻ or Hg₂Se₂²⁻. In some embodiments, a metal chalcogenide complex has an anionic component of Sn₂S₆⁴⁻, SnS₄⁴⁻, Sn₂Se₆⁴⁻ or SnSe₄⁴⁻.

In other embodiments, an inorganic ligand is a hydrogen chalcogenide anion, such as HS⁻, HSe⁻ or HTe⁻. Further, an inorganic ligand can be a chalcogenide anion such as S²⁻, Se²⁻ or Te²⁻. In some embodiments, an inorganic ligand is a binary chalcogenide anion such as TeS₃²⁻. A “binary chalcogenide anion,” for reference purposes herein, comprises an anion formed of two different chalcogenide elements. Alternatively, an inorganic ligand is a neutral species comprising at least one metal or metalloid and a chalcogenide, such as In₂Te₃, Ga₂Se₃, CuInSe₂, ZnTe, or Sb₂Se₃. In further embodiments, an inorganic ligand is a Na⁺ or NH₄⁺ complex of one or more of the anionic species described above, such as Na₄[Sn₂S₆], Na₄[SnS₄], Na₄[Sn₂Se₆], Na₄[SnSe₄], Na₄[Sn₂Te₆], Na₄[SnTe₄], and (NH₄⁺)₂[TeS₃].

Inorganic ligands described herein can be associated with surfaces of copper-zinc-tin-chalcogenide nanoparticles in any manner not inconsistent with the objectives of the present invention. In some cases, an inorganic ligand is covalently bonded to the surface of the nanoparticle, such as through one or more coordinate covalent bonds or one or more metal-chalcogenide bonds, including metal-sulfur or metal-selenide bonds. In some embodiments, an inorganic ligand is bonded to the surface of the nanoparticle through one or more hydrogen bonds or one or more ionic bonds. In some embodiments, an inorganic ligand is associated with the surface of the nanoparticle through one or more electrostatic interactions, one or more hydrophobic interactions or one or more van der Waals interactions.

Nanoparticle compositions described herein also comprise a polar liquid carrier. Any polar liquid carrier not inconsistent with the objectives of the present invention may be used. For example, a polar liquid carrier can be water or an alcohol such as methanol, ethanol, or propanol. In some cases, a polar liquid carrier comprises one or more of formamide, dimethylformamide (DMF), ethyl acetate, acetone, acetonitrile, dimethylsulfoxide (DMSO), tetrahydrofuran (THF), and aqueous ammonia.

Moreover, nanoparticles of copper-zinc-tin-chalcogenide and associated inorganic surface ligands can be present in the liquid carrier in any amount not inconsistent with the objectives of the present invention. In some embodiments, nanoparticles of copper-zinc-tin-chalcogenide can be present in the liquid carrier in an amount of up to 10 weight percent or up to 5 weight percent, based on the total weight of the nanoparticles and the liquid carrier. In some cases, nanoparticles of copper-zinc-tin-chalcogenide are present in the liquid carrier in an amount between 0.01 weight percent and 10 weight percent or between 0.1 weight percent and 5 weight percent, based on the total weight of the nanoparticles and the liquid carrier.

### II. Methods of Making a Polycrystalline Film

In another aspect, methods of making a polycrystalline film are described herein. In some embodiments, a method of making a polycrystalline film comprises providing a nanoparticle composition comprising crystalline nanoparticles of copper-zinc-tin-chalcogenide disposed in a polar liquid carrier, wherein inorganic ligands are associated with surfaces of the copper-zinc-tin-chalcogenide nanoparticles, and depositing the nanoparticle composition on a substrate surface. The liquid carrier is removed to provide the polycrystalline film of copper-zinc-tin-chalcogenide. In some cases, the nanoparticles are dispersed throughout the polar liquid carrier. Inorganic ligands associated with surfaces of the copper-zinc-tin-chalcogenide nanoparticles can be formed of any metal chalcogenide complex, chalcogenide complex or chalcogenide described in Section I above.

The deposited polycrystalline film of copper-zinc-tin-chalcogenide can be heated. In some cases, the polycrystalline film is heated at a temperature in excess of 200° C. or a temperature in excess of 300° C. For example, a polycrystalline film can be heated at a temperature between about 300° C. and about 600° C. Alternatively, a polycrystalline film is heated at a temperature no greater than about 250° C., such as between 100° C. and 250° C. or between 100° C. and 200° C. In some embodiments, the polycrystalline film is heated at a temperature greater than the boiling point of the liquid carrier of the nanoparticle composition used to make the film.

Heating a polycrystalline film as described herein can result in annealing and/or sintering of the film. Alternatively, a polycrystalline film is not annealed or sintered following formation of the film.

It has been found that in some cases wherein an inorganic ligand is used and the polycrystalline film is heated, chalcogenide from the inorganic ligand can be incorporated into crystalline grains of the copper-zinc-tin-chalcogenide film during the heating. Further, metal from the inorganic ligands can also be incorporated into grains of the polycrystalline film. For example, inorganic ligands of a metal chalcogenide complex having an anionic component of Sn₂S₆⁴⁻ or SnS₄⁴⁻ can be used, and the polycrystalline film of copper-zinc-tin-chalcogenide is heated at a temperature in excess of 200° C. In such embodiments, sulfur from the metal chalcogenide complex can be incorporated into crystalline grains of the copper-zinc-tin-chalcogenide. Moreover, in some cases, sulfur content of crystalline grains of the copper-zinc-tin-chalcogenide film can remain substantially unchanged after film heating due to incorporation of sulfur from the inorganic ligands. In some embodiments, sulfur content of the crystalline grains is altered less than 5 percent or less than 1 percent by the heating process. Additionally, in some embodiments, sulfur can be present in the copper-zinc-tin-chalcogenide of a film in near stoichiometric amount, both before and after heating. A “near stoichiometric” amount for reference purposes herein, comprises an amount within about 10 percent, within about 5 percent, or within about 1 percent of a stoichiometric amount, where the stoichiometric amount of sulfur in copper-zinc-tin-sulfide is 4. Incorporation of chalcogenide from inorganic ligands into the polycrystalline film of copper-zinc-tin-chalcogenide can mitigate chalcogenide loss in the film during heating operations. Such mitigation can preclude use of toxic/corrosive atmospheres, such as H₂S, during crystalline film annealing.

Moreover, similar results can be achieved when a ligand formed of a metal chalcogenide complex comprising selenium is used instead of or in addition to an inorganic ligand comprising sulfur. In some embodiments, for example, a method described herein further comprises selenizing a polycrystalline film of copper-zinc-tin-chalcogenide, wherein selenium from the inorganic ligand metal chalcogenide complex is incorporated into crystalline grains of the copper-zinc-tin-chalcogenide. Selenizing the film, in some cases, can be carried out by heating the film in a manner described herein, such as at a temperature in excess of about 300° C. or at a temperature of less than about 250° C. In addition, in some embodiments, selenizing results in an increase of the grain size of the crystalline grains of the polycrystalline film. Further, in some embodiments, selenizing by inorganic ligand selenium incorporation is achieved without the use of a selenium-containing gas such as H₂Se during the heating step. Copper-zinc-tin-chalcogenide films suitable for selenization methods described herein include CuZnSnS, CuZnSnSe and CuZnSnSSe.

It is also possible to incorporate metal from an inorganic ligand described herein into crystalline grains of a film of copper-zinc-tin-chalcogenide during a heating step. For example, inorganic ligands formed of a metal chalcogenide complex having an anionic component of Sn₂S₆⁴⁻, SnS₄⁴⁻, Sn₂Se₆⁴⁻ and/or SnSe₄⁴⁻ can be employed, resulting in tin from the inorganic ligands being incorporated into crystalline grains of the copper-zinc-tin-chalcogenide during heating. As described above, such metal incorporation can mitigate tin loss from the crystalline grains during heating or annealing. In some embodiments, tin can be present in the copper-zinc-tin-chalcogenide in a stoichiometric or near stoichiometric amount before and after heating.

Although the foregoing description of the sulfurization, selenization, and/or metallization of a polycrystalline film described herein refers to the use of metal chalcogenide ligands, it is to be understood that other inorganic ligands described herein may also be used to provide a polycrystalline film having a desired chalcogenide and/or metal content as described herein. For instance, in some embodiments, a ligand formed of a chalcogenide or chalcogenide complex can also be used to provide sulfurization, selenization, and/or metallation in a manner described herein, including in the absence of a reactive gas.

Alternatively, nanoparticle compositions comprising organic ligands can be used to form a polycrystalline film described herein. In some embodiments, for example, a method of making a polycrystalline film comprises providing a nanoparticle composition comprising crystalline nanoparticles of copper-zinc-tin-chalcogenide disposed in a liquid carrier, wherein organic ligands are associated with surfaces of the nanoparticles, the organic ligands comprising an amine, carboxylic acid, carboxylate, phosphine, phosphine oxide, phosphonate, phosphinate, or thiol having an alkyl or alkenyl moiety comprising 2 to 8 carbon atoms. The method further comprises depositing the nanoparticle composition on a substrate surface and removing the liquid carrier to provide the polycrystalline film of copper-zinc-tin-chalcogenide. Further, in some embodiments, the nanoparticles of copper-zinc-tin-chalcogenide are dispersed throughout the liquid carrier. The liquid carrier, in some cases, is a non-polar liquid carrier such as benzene, tolune, or hexane.

Moreover, it is also possible to form a polycrystalline film of copper-zinc-tin-chalcogenide from nanoparticles using a ligand-exchange procedure. In some embodiments, for example, a method of making a polycrystalline film comprises providing crystalline nanoparticles of copper-zinc-tin-chalcogenide having first ligands associated with surfaces of the nanoparticles; combining the nanoparticles with second ligands; replacing the first ligands with the second ligands on the nanoparticle surfaces to provide ligand-exchanged nanoparticles; dispersing the ligand-exchanged nanoparticles in a liquid carrier to provide a nanoparticle composition; depositing the nanoparticle composition on a substrate surface; and removing the liquid carrier to provide the polycrystalline film of copper-zinc-tin-chalcogenide. Replacing the first ligands with the second ligands, in some embodiments, comprises replacing at least about 50 mole percent, at least about 70 mole percent, at least about 90 percent mole or at least about 95 mole percent of the first ligands with the second ligands. In some cases, replacing the first ligands with the second ligands comprises replacing all of the first ligands with the second ligands. In some embodiments, the first ligands bind to the surfaces of the nanoparticles less strongly than the second ligands, thereby permitting displacement by the second ligands.

In some instances, the first ligands provide a larger interparticle spacing than that of the second ligands, where the “interparticle spacing” refers to the average distance between adjacent nanoparticles provided by the steric hindrance and/or electrostatic repulsion of the ligands. In some cases, for instance, the first ligands have a higher weight average molecular weight and/or a greater hydrocarbon chain length than the second ligands.

Any combination of first and second ligands not inconsistent with the objectives of the present invention may be used in a ligand-exchange procedure described herein. In some embodiments, for example, the first ligands comprise an amine, carboxylic acid, carboxylate, phosphonate or phosphonite having an alkyl or alkenyl moiety comprising 10 or more carbon atoms, such as oleic acid or oleylamine. Further, the second ligands can comprise a thiol, phosphonate, phosphate or phosphinite having an alkyl or alkenyl moiety comprising 2 to 12 carbon atoms or 2 to 8 carbon atoms. In some embodiments, for example, a second ligand is selected from the group consisting of propanethiol, methyl 3-mercaptopropionate, 1-butanethiol, 2-methyl-1-propanethiol, 2-methyl-2-propanethiol, 1-pentanethiol, 3-methyl-1-butanethiol, 1-hexanethiol, butyl 3-mercaptopropionate, 1-heptanethiol, 1-octanethiol, 2-ethylhexanethiol, 1-nonanethiol, 1-decanethiol, 1-undecanethiol, 1-dodecanethiol, tert-dodecylmercaptan, 11-mercaptoundecyl trifluoroacetate, 1-tetradecanethiol, 1-pentadecanethiol and 1-hexadecanethiol.

A ligand-exchange procedure can be carried out using a single phase or multiple phases. For example, in a multi-phase process, nanoparticles and associated first ligands are dispersed in a first non-polar solvent such as benzene, toluene or hexane. A composition of second ligands dispersed in a solvent that is immiscible or partially immiscible with the first non-polar solvent is provided. The at least partially immiscible solvent can be a polar solvent such as water or an alcohol. The second ligand composition is mixed with the nanoparticles and associated first ligands resulting in the formation of a two-layer or two-phase solvent system. The two-phase solvent system is stirred or otherwise agitated to effect replacement of the first ligands with the second ligands. Successful ligand-exchange can be identified by the migration of the nanoparticles from one layer or phase to the other layer or phase (such as from a non-polar layer to a polar layer).

Alternatively, a single-phase process can be used wherein the second ligands and nanoparticles associated with the first ligands are not disposed in different solvents, but are instead present in the same solvent or liquid carrier.

In addition, one or more steps of a ligand-exchange procedure described herein can be carried out at elevated temperature. In some embodiments, replacing the first ligands with the second ligands is carried out at a temperature between about 30° C. and about 100° C. or between about 30° C. and about 80° C. In some cases, replacing the first ligands with the second ligands is administered at a temperature above room temperature (25° C.) but below the lowest boiling point of any solvent or liquid carrier using during the ligand replacement process.

Polycrystalline copper-zinc-tin-chalcogenide films formed by a method described herein can have any physical dimensions or microstructure not inconsistent with the objectives of the present invention. For example, in some embodiments, a film has a thickness selected from Table I.

TABLE I
Copper-Zinc-Tin-Chalcogenide Film Thickness

100 nm-10 μm
500 nm-5 μm
100 nm-1 μm
1-10 μm
>10 μm

Moreover, in some cases, a film having a thickness described herein is also free or substantially free of cracks or voids, such as cracks or voids having a dimension greater than about 100 nm or greater than about 500 nm.

Additionally, a polycrystalline copper-zinc-tin-chalcogenide film formed by a method described herein can be a nanocrystalline film. A nanocrystalline film, in some embodiments, comprises crystalline grains that are the same size or substantially the same size as the copper-zinc-tin-chalcogenide nanoparticles used to form the film. For example, in some cases, a nanocrystalline film has an average grain size that is within about 15 percent, within about 10 percent, within about 5 percent or within about 1 percent of the average size of the copper-zinc-tin-chalcogenide nanoparticles used to form the film, where the average size of the nanoparticles refers to the size of the copper-zinc-tin-chalcogenide core, as opposed to the size of the core plus the ligands. Alternatively, the average grain size of the polycrystalline film is in excess of 100 nm, 500 nm or 1 μm. Polycrystalline film grain size, in some embodiments, can be varied according to size and/or chemical composition of the copper-zinc-tin-chalcogenide nanoparticles used to form the film, the chemical composition of the nanoparticle ligands and/or the manner of heating the deposited film. Moreover, in some cases, inorganic ligands or organic ligands described herein can be present in a polycrystalline film

Polycrystalline films formed by a method described herein can also exhibit one or more desired electronic properties. For example, in some cases, a polycrystalline film described herein has a carrier mobility selected from Table II.

TABLE II
Carrier Mobility of Copper-zinc-tin-chalcogenide polycrystalline film

| | |
|---|---|
| ≧8 | cm²/Vs |
| ≧10 | cm²/Vs |
| 6-20 | cm²/Vs |
| 8-15 | cm²/Vs |
| 8-12 | cm²/Vs |
| 10-15 | cm²/Vs |

Moreover, polycrystalline films having a carrier mobility selected from Table II can be formed by using any combination of nanoparticles, ligands, and process steps described in this Section II and Section I hereinabove. For example, a polycrystalline film having a carrier mobility of at least 8 cm²/Vs is formed from a nanoparticle composition comprising crystalline nanoparticles of copper-zinc-tin-chalcogenide disposed in a polar liquid carrier, wherein inorganic ligands are associated with surfaces of the copper-zinc-tin-chalcogenide nanoparticles, the inorganic ligands formed of a metal chalcogenide complex. In some embodiments, an annealed, sulfurized, selenized, and/or metallated polycrystalline film described herein has a carrier mobility of at least 10 cm²/Vs.

Polycrystalline films of copper-zinc-tin-chalcogenide described herein can be deposited on any substrate surface not inconsistent with the objectives of the present invention. For example, a substrate surface can be formed of an inorganic material such as an inorganic oxide or inorganic glass. In some embodiments, a substrate surface is formed from a glass or ceramic material such as alumina, quartz, or silica. A substrate surface can also be formed of a metal plate or metal foil, such as an aluminum, steel, or stainless steel plate or foil. Alternatively, a substrate surface is formed of an organic material, such as an organic polymeric material. In some embodiments, a substrate surface is formed of plastic. The use of a plastic material, in some cases, can provide a flexible substrate.

Moreover, depositing the nanoparticle composition of copper-zinc-tin-chalcogenide nanoparticles and associated surface ligands in a liquid carrier on a substrate surface can be administered in any manner not inconsistent with the objectives of the present invention. In some embodiments, depositing the nanoparticle composition on a substrate surface comprises casting the composition onto the substrate surface, such as by spin coating, spray casting or drop casting. In some cases, depositing the nanoparticle composition on a substrate surface comprises blade coating or roll-to-roll coating the composition onto the surface.

Methods of making a polycrystalline film described herein also include removing the liquid carrier to provide the polycrystalline film of copper-zinc-tin-chalcogenide. The liquid carrier can be removed in any manner not inconsistent with the objectives of the present invention. In some embodiments, for instance, the liquid carrier is removed by drying the nanoparticle composition on the substrate surface. In some cases, drying is carried out by permitting the liquid carrier to evaporate at ambient temperature and pressure, such as at standard temperature and pressure (STP). In some instances, drying is carried out by directing a stream of gas over the surface of the nanoparticle composition deposited on the substrate. The gas can be air or an inert gas such as helium, nitrogen, or argon. Other gases may also be used. Further, in some embodiments, a liquid carrier can be removed by heating the nanoparticle composition deposited on the substrate, including at a temperature described hereinabove. Heating a polycrystalline film can be carried out in any manner not inconsistent with the objectives of the present invention. In some embodiments, for instance, heating is carried out by placing the substrate on a hotplate or in an oven. Other methods of heating may also be used.

### III. Electronic Devices

In another aspect, electronic devices are described herein. In some embodiments, an electronic device comprises a first electrode or terminal, a second electrode or terminal and a polycrystalline film in electrical communication with the first electrode or terminal and the second electrode or terminal, wherein the polycrystalline film comprises a film formed by a method in Section II above. Such a polycrystalline film can be used as a semiconductor layer or other photoactive layer in any electronic device architecture, including optoelectronic device architectures, not inconsistent with the objectives of the present invention. In some embodiments, for instance, the optoelectronic device is a solar cell or photovoltaic device, the photovoltaic device comprising a first electrode, a second electrode, and a polycrystalline film described herein disposed between the first electrode and the second electrode. In other cases, the electronic device is a field effect transistor (FET), the FET comprising a source terminal, a drain terminal, a gate terminal, and a polycrystalline film described herein in electrical communication with the source terminal and the drain terminal.

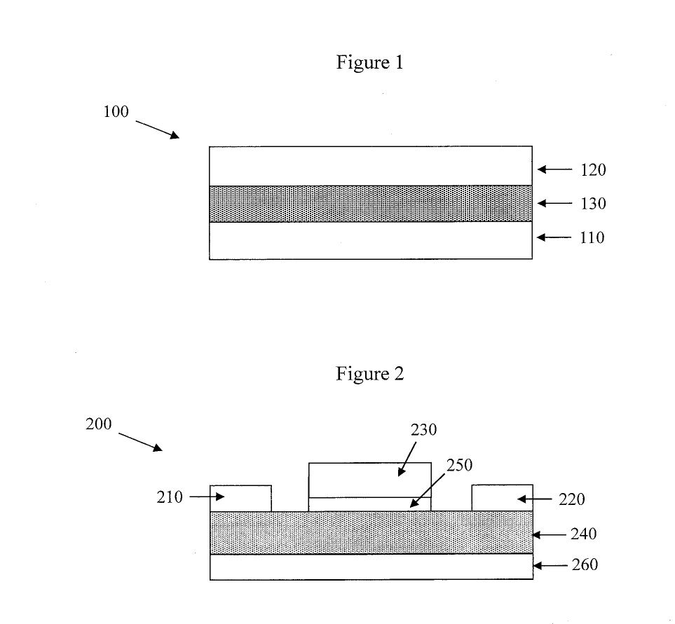

Some non-limiting examples of electronic devices will now be further described with reference to the drawings. FIG. 1 illustrates a sectional view of an electronic device according to one embodiment described herein. The device (100) is a photovoltaic device comprising a first electrode (110), a second electrode (120), and a polycrystalline film (130) described herein disposed between the first electrode (110) and the second electrode (120). In some embodiments, the first electrode (110) and/or second electrode (120) can be radiation transmissive. Although the device (100) is depicted as having only three components, as understood by one of ordinary skill in the art, other components may also be used, such as one or more charge transfer layers or one or more exciton blocking layers (EBL).

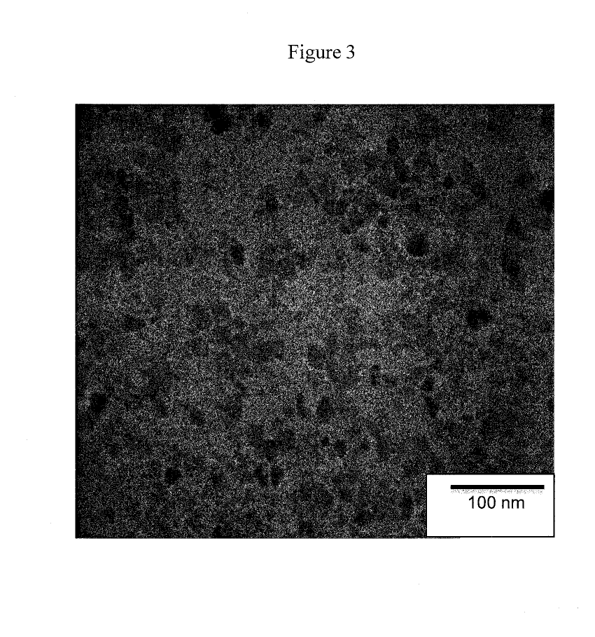

FIG. 2 illustrates a sectional view of an electronic device according to another embodiment described herein. The device (200) is a field effect transistor comprising a source terminal (210), a drain terminal (220), and a gate terminal (230). A polycrystalline film described herein (240) is in electrical communication with the source terminal (210) and drain terminal (220). A dielectric layer (250) is positioned between the gate terminal (230) and the polycrystalline film (240). In addition, the polycrystalline film (240) is disposed on an insulating substrate (260). Any insulating substrate not inconsistent with the objectives of the present invention may be used. In some embodiments, insulating substrate (260) comprises glass such as silica.

Additional embodiments will now be further described with reference to the following non-limiting examples.

### EXAMPLE 1

### Inorganic Ligands

Inorganic ligands suitable for use in some nanoparticle compositions and methods described herein were prepared as follows.

Ligands formed of chalcogenides comprising sulfur or selenium were prepared by combining one or more of K₂S, Na₂S, K₂Se, and Na₂Se with copper-zinc-tin-chalcogenide nanoparticles described herein. The potassium and sodium chalcogenide reagents were purchased commercially and used as received (Alfa Aesar, 99.8% for sodium selenide, 98% for sodium sulfide; Strem Chemicals, Inc, 95% for potassium sulfide).

Ligands comprising a hydrogen chalcogenide such as HSe⁻ and HTe⁻ were prepared by treating a solution of KOH or NaOH in formamide with H₂Se or H₂Te gas. Briefly, for the case of KOH, under room temperature in a three-neck flask, KOH was dissolved in formamide to prepare a 0.05 M solution. HAl₂Se₃ (or Al₂Te₃) was added to another three-neck flask and H₂Se (or H₂Te) gas was produced in situ by injecting 10% H₂SO₄ into the flask. The second three-neck flask was in fluid communication with the first three-neck flask containing the KOH solution. In this manner, the H₂Se (or H₂Te) gas was used to treat the KOH solution. Prior to initiating the reaction by injecting H₂SO₄, both three-neck flasks and the H₂SO₄ were purged with argon for 30 minutes. A 2-fold molar excess of H₂Se (or H₂Te) was used. The H₂Se (or H₂Te) gas was passed through the KOH solution slowly to form KHSe (or KHTe) in formamide. An inert gas environment such as an N₂ environment was required to subsequently handle the synthesized KHSe or KHTe.

Ligands formed of (NH₄)₂TeS₃ were synthesized by dissolving 1 g of 2 TeO₂.3HNO₃ in 30 mL of aqueous ammonia solution (approximately 30% NH₃) in a two-neck flask at room temperature. The solution was purged with argon for 30 minutes and then purged with H₂S until the solids were entirely dissolved, forming a clear yellow solution. Pure product was obtained by vacuum evaporation to remove the solvents and by-products, including (NH₄)₂S.

Ligands comprising an anionic component of Sn₂S₆⁴⁻ or SnS₄⁴⁻ were prepared by reacting sodium sulfide with tin (IV) chloride as follows:

6Na₂S+2SnCl₄→Na₄Sn₂S₆+8NaCl

4Na₂S+SnCl₄→Na₄SnS₄+4NaCl

For SnS₄⁴⁻, 12 mmol Na₂S.9H₂O and 3 mmol SnCl₄.5H₂O were dissolved in 8 mL and 2 mL H₂O, respectively. Then, in a water bath at 45° C., the SnCl₄ solution was added dropwise into the Na₂S solution under vigorous stirring. The resulting solution was kept at 45° C. for 12 h, followed by the addition of 5 mL methanol (or 10 mL acetone) with stirring for another 12 h.

The solution was kept in a refrigerator for 48 h to form white precipitate crystals of Na₄SnS₄.14H₂O. The crystals were washed with methanol (or acetone) several times and dried under vacuum.

For Sn₂S₆⁴⁻, a similar procedure was followed. The only variation was changing the amount of SnCl₄.5H₂O from 3 mmol to 4 mmol.

### EXAMPLE 2

### Nanoparticle Composition

A nanoparticle composition according to one embodiment described herein was prepared as follows. First, copper-zinc-tin-sulfide (CZTS) nanoparticles were prepared. The amounts of Cu, Zn, and Sn precursors were chosen to obtain Cu-poor, Sn-rich nanoparticles. Briefly, 1.332 mmol of copper(II) acetylacetonate, 0.915 mmol of zinc acetylacetonate, and 0.75 mmol of tin (IV) bis(acetylacetonate) dibromide were dissolved in 10 mL of oleylamine (OLA) and then transferred into a two-neck flask connected to a Schlenk line and equipped with a heating mantle. The solution was degassed by heating the solution to 135° C. under vacuum and then purging with argon several times. An argon atmosphere was provided to the flask, and the solution was heated to 225° C.

Meanwhile, in a separate flask, 0.16 g sulfur powder was dissolved in 5 mL of OLA and purged with argon for 30 minutes. This solution of sulfur in OLA was then quickly injected into the 225° C. precursor mixture. Following injection, the solution immediately turned dark brown. The color then changed to black after holding the reaction flask at 225° C. for 25 minutes.

The heating mantle was then removed from the reaction flask, and the reaction mixture was allowed to cool to 80° C. Next, 40 mL of methanol was added to the flask, resulting in the precipitation of the nanoparticles from solution. The nanoparticles were isolated from the supernatant by centrifugation at 5000 rpm for 10 minutes. The nanoparticles were then further purified by two cycles of dispersion in 12 mL of toluene, followed by precipitation with 40 mL of methanol and subsequent centrifugation. The purified nanoparticles were then redispersed in 20 mL of toluene. This solution of OLA-capped nanoparticles was then available for use in a method described herein.

To provide a series of ligand-exchanged nanoparticle compositions, two methods were employed, depending on the identity of the replacement ligands. In instances wherein the replacement ligands were sufficiently soluble in a non-polar solvent such as toluene, a single-phase method was used. In cases wherein the replacement ligands were not sufficiently soluble in a non-polar solvent, a two-phase method was used.

In the single-phase method, the solution of nanoparticles in toluene described above was divided into four 5-mL portions. Next, 0.2 mmol of 1-butanethiol, 1-hexanethiol, or 1-dodecanethiol was added to each of three of the 5-mL portions. The mixtures were allowed to stir for 5 hours at room temperature to replace the original OLA ligands with the alkylthiol ligands. The ligand-exchanged nanoparticles were purified by three cycles of precipitation with methanol followed by centrifugation and redispersal in toluene. Nanoparticle powders purified in this manner were then dried under argon for further use.

In the two-phase method, a replacement ligand such as an inorganic ligand described in Example 1 was dissolved in a polar solvent such as hydrazine, formamide, or aqueous ammonia to provide a mixture having a ligand concentration of about 0.01 M to about 0.1 M. This mixture was then combined with a mixture of the OLA-capped CZTS nanoparticles in toluene. The concentration of the CZTS nanoparticles in toluene was about 5 mg/mL to about 50 mg/mL. Combining the two mixtures in this manner provided a two-phase mixture. This two-phase mixture was then agitated by stirring or vortexing for a time period sufficient to achieve a desired amount of ligand exchange. The time period was typically between several minutes and 24 hours. Successful ligand exchange was identified by the transfer of black color from the toluene phase to the polar phase.

The CZTS nanoparticles were analyzed by transmission electron microscopy (TEM), powder x-ray diffraction (XRD), and x-ray photoelectron spectroscopy (XPS). FIG. 3 illustrates a TEM image of CZTS nanoparticles according to one embodiment described herein. The CZTS nanoparticles had a size distribution within the range of 15 nm to 25 nm. Powder XRD results indicated a good match between the diffraction peaks of the CZTS nanoparticles and the JCPDS database for so-called stoichiometric CZTS (Cu₂ZnSnS₄). The XPS spectrum indicated that the composition of the as-synthesized CZTS nanoparticles was Cu_{1.81}Zn_{1.02}Sn_{0.88}S₄, determined by data taken at 5 different points in the dried nanoparticle powder sample.

### EXAMPLE 3

### Polycrystalline Films

Polycrystalline films according to some embodiments described herein were prepared as follows. First, nanoparticle compositions were prepared in a manner similar to that described in Example 2. Next, different nanoparticle compositions comprising CZTS nanoparticles stabilized by different ligands were used to form polycrystalline films. Each nanoparticle composition included CZTS nanoparticles dispersed in 15 mL of toluene. Each composition was spray cast onto a separate ITO substrate (2 cm×2 cm) at a constant temperature of 180° C. The spraying speed was 1 mL/min, and the nitrogen flow pressure was 10 psi. For current-voltage (I-V) characterization of the films, electrodes formed of 5 nm molybdenum oxide (MoO₃) and 200 nm aluminum were deposited via thermal evaporation at a pressure of 10⁻⁶ torr. For ultraviolet (UV)-absorption characterization, each composition was spray casted onto a glass substrate instead of an ITO substrate, using the same technique as above, and no electrodes were provided.

The morphology and thickness of the films was measured by scanning electron microscopy (JEOL SEM, JSM-6330F). Current-voltage characteristics were collected using a Keithley 236 source-measurement unit.

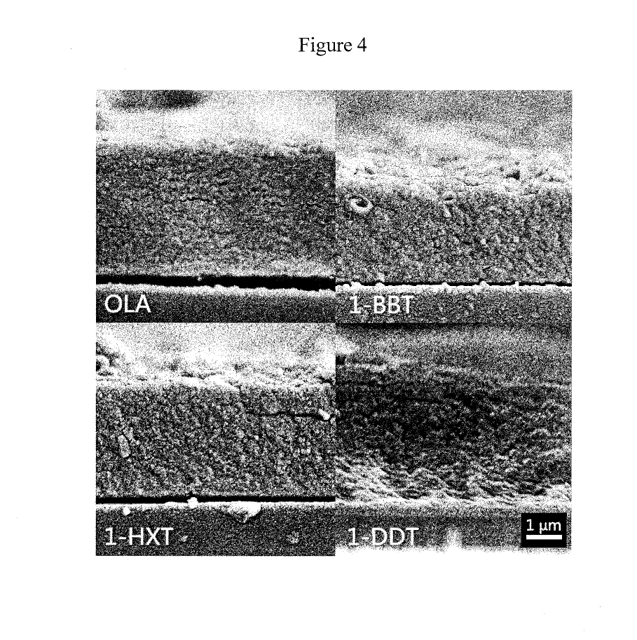

FIG. 4 illustrates SEM images of films formed from CZTS nanoparticles stabilized with OLA (OLA), CZTS nanoparticles ligand-exchanged with 1-butanethiol (1-BTT), CZTS nanoparticles ligand-exchanged with 1-hexanethiol (1-HXT), and CZTS nanoparticles ligand-exchanged with 1-dodecanethiol (1-DDT). As illustrated by FIG. 4, all four films were condensed, homogeneous films and were more than 1 μm thick.

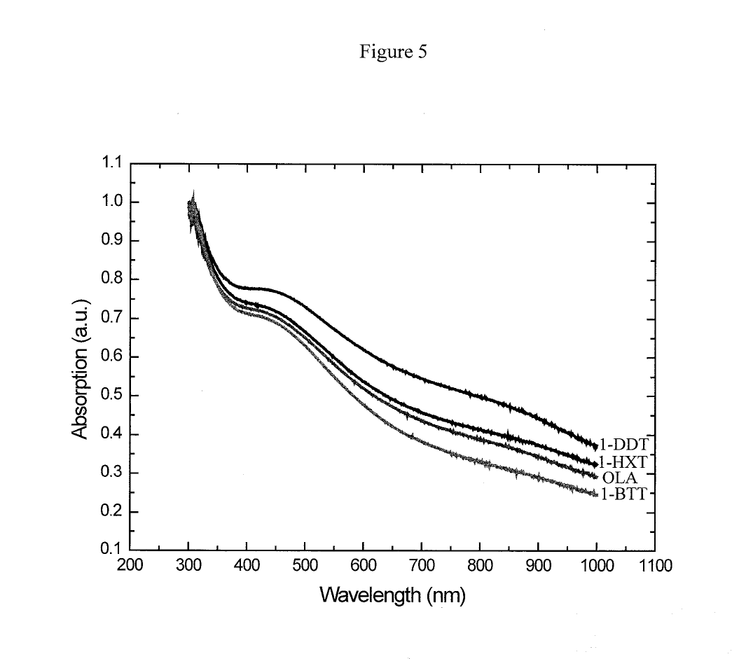

FIG. 5 illustrates the absorption profiles of films formed from CZTS nanoparticles stabilized with OLA (OLA), CZTS nanoparticles ligand-exchanged with 1-butanethiol (1-BTT), CZTS nanoparticles ligand-exchanged with 1-hexanethiol (1-HXT), and CZTS nanoparticles ligand-exchanged with 1-dodecanethiol (1-DDT).

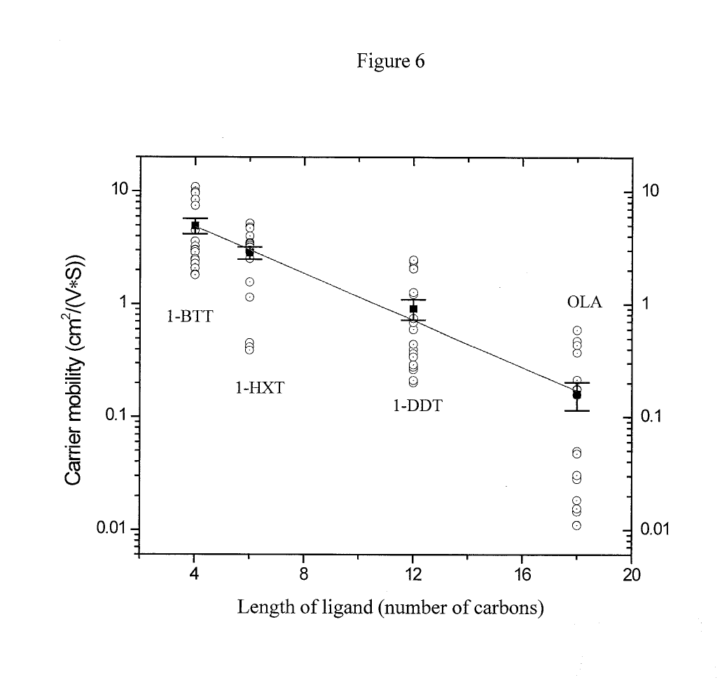

FIG. 6 illustrates the carrier mobilities of films formed from CZTS nanoparticles stabilized with OLA (OLA), CZTS nanoparticles ligand-exchanged with 1-butanethiol (1-BTT), CZTS nanoparticles ligand-exchanged with 1-hexanethiol (1-HXT), and CZTS nanoparticles ligand-exchanged with 1-dodecanethiol (1-DDT). The carrier mobility values were extracted from I-V characteristics using Equation (1):

$$J = \frac{9}{8} {ɛ}_{0} ɛ {μ}_{0} exp ( 0.89 β \sqrt{V / d} ) \frac{{V}^{2}}{{d}^{3}} , \qquad ( 1 )$$

wherein V is the applied voltage, d is the thickness of the film, μ₀ is the carrier mobility, ε₀ is the permittivity of free space, and ε is the dielectric constant. The efficiency β was determined by Equation (2):

$$β = \frac{1}{{K}_{B} T} {( \frac{{q}^{3}}{π {ɛ}_{0} ɛ} )}^{1 / 2} , \qquad ( 2 )$$

wherein K_{B} is the Boltzmann constant, T is temperature, and q is charge.

As shown in FIG. 6, the measured carrier mobility sharply increased when the chain length of the ligands decreased. The observed difference between films formed from OLA-capped CZTS nanoparticles (OLA) and 1-butanethiol-capped CZTS nanoparticles was surprisingly large: the carrier mobility using 1-butanethiol was improved about 29 times compared to using OLA.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

1-8. (canceled)

9. A method of making a polycrystalline film comprising:
providing a nanoparticle composition comprising crystalline nanoparticles of copper-zinc-tin-chalcogenide disposed in a polar liquid carrier, wherein inorganic ligands are associated with surfaces of the copper-zinc-tin-chalcogenide nanoparticles, the inorganic ligands formed of a metal chalcogenide complex;
depositing the nanoparticle composition on a substrate surface; and
removing the polar liquid carrier to provide the polycrystalline film of copper-zinc-tin-chalcogenide, the polycrystalline film having a carrier mobility of at least 8 cm²/Vs.

10. The method of claim 9, wherein the nanoparticles of copper-zinc-tin-chalcogenide are dispersed throughout the polar liquid carrier.

11. The method of claim 9, wherein the nanoparticles of copper-zinc-tin-chalcogenide are of the formula CuₐZn_{b}Sn_{c}(S_{1-d}Se_{d})_{c}, wherein 1.2≦a≦2.5, 0.8≦b≦1.2, 0.5≦c≦1.5, 0≦d≦1 and 3.5≦e≦4.5.

12. The method of claim 11, wherein d=0.

13. The method of claim 9, wherein the metal chalcogenide complex is formed of one or more metallic elements selected from Groups IB, IIB, MA and IVA of the Periodic Table and one or more of sulfur, selenium and tellurium.

14. The method of claim 13, wherein the metal chalcogenide complex is anionic.

15. The method of claim 13, wherein the metal chalcogenide complex has an anionic component of Sn₂S₆⁴⁻ or SnS₄⁴⁻.

16. The method of claim 13, wherein the metal chalcogenide complex has an anionic component of Sn₂Se₆⁴⁻ or SnSe₄⁴⁻.

17. (canceled)

18. The method of claim 15 further comprising heating the polycrystalline film of copper-zinc-tin-chalcogenide at a temperature in excess of 200° C., wherein sulfur from the metal chalcogenide complex is incorporated into crystalline grains of the copper-zinc-tin-chalcogenide.

19. The method of claim 18, wherein the heating is conducted in the absence of H₂S.

20. The method of claim 19, wherein the copper-zinc-tin-chalcogenide is copper-zinc-tin-sulfide with sulfur present in near stoichiometric amount.

21. The method of claim 18, wherein tin from the metal chalcogenide complex is incorporated into crystalline grains of the copper-zinc-tin-chalcogenide.

22. The method of claim 21, wherein tin is present in the copper-zinc-tin-chalcogenide in near stoichiometric amount.

23. The method of claim 19, wherein heating comprises annealing the polycrystalline film of copper-zinc-tin-chalcogenide and the annealed polycrystalline film has a carrier mobility of at least 10 cm²/Vs.

24. The method of claim 9, wherein the metal chalcogenide complex comprises selenium.

25. The method of claim 24 further comprising selenizing the polycrystalline film of copper-zinc-tin-chalcogenide at a temperature in excess of 200° C., wherein selenium from the metal chalcogenide complex is incorporated into crystalline grains of the copper-zinc-tin-chalcogenide.

26. The method of claim 25, wherein the selenizing is conducted in the absence of H₂Se.

27. The method of claim 26, wherein the copper-zinc-tin-chalcogenide is copper-zinc-tin-sulfide.

28. The method of claim 25, wherein the selenized polycrystalline film of copper-zinc-tin-chalcogenide has a carrier mobility of at least 10 cm²/Vs.

29. The method of claim 25, wherein tin from the metal chalcogenide complex is incorporated into crystalline grains of the copper-zinc-tin-chalcogenide.

30. (canceled)

31. The method of claim 15, wherein the method does not comprise heating the polycrystalline film of copper-zinc-tin-chalcogenide and the polycrystalline film of copper-zinc-tin-chalcogenide has a carrier mobility of at least 10 cm²/Vs.

32-57. (canceled)
